(19) United States
(12) Patent Application Publication
(10) Pub. No.: US 2025/0183079 A1
(43) Pub. Date: Jun. 5, 2025

(54) Substrate Transport System and Substrate Position Adjustment Method

(71) Applicant: Tokyo Electron Limited, Tokyo (JP)

(72) Inventor: Keisuke KONDOH, Yamanashi (JP)

(21) Appl. No.: 19/049,351

(22) Filed: Feb. 10, 2025

Related U.S. Application Data
(63) Continuation of application No. PCT/JP2023/040045, filed on Nov. 7, 2023.

(30) Foreign Application Priority Data
Nov. 7, 2022 (JP) 2022-178163

(51) Int. Cl. H01L 21/68; H01L 21/67; H01L 21/687

(52) U.S. Cl. CPC H01L 21/68; H01L 21/67167; H01L 21/68707; H01L 21/6875

(57) ABSTRACT

A substrate transfer system comprises a transfer unit having a holding member configured to hold at least two substrates, a plurality of mounting tables, support members that are provided to each of the mounting tables and are capable of moving relatively in a vertical direction with respect to each of the mounting tables, and a plurality of movement units that independently move each of the support members in the horizontal direction. A position adjustment of each of the substrates with respect to each of the mounting tables is performed by a first substrate movement, in which each of the substrates in a state of being held by the holding member is moved by the transfer unit, and a second substrate movement, in which each of the substrates in a state of being supported by each of the support members is moved by the movement units.

### CROSS-REFERENCE TO RELATED APPLICATIONS

This application is a bypass continuation application of International Application No. PCT/JP2023/040045 having an international filing date of Nov. 7, 2023 and designating the United States, the International Application being based upon and claiming the benefit of priority from Japanese Patent Application No. 2022-178163 filed on Nov. 7, 2022, each of which are hereby incorporated by reference in its entirety.

### TECHNICAL FIELD

The present disclosure relates to a substrate transfer system and a substrate position adjustment method.

### BACKGROUND

When plasma processing is performed on a wafer, for example, it is necessary to accurately dispose the wafer at a predetermined position within a process chamber. Accordingly, conventionally, various methods for aligning the wafer have been proposed. For example, Japanese Laid-open Patent Publication No. 2008-066372 discloses an apparatus including a transfer arm for transferring a wafer, a mounting table on which the wafer is mounted, a substrate transfer device for transferring the wafer from the transfer arm to the mounting table, and a substrate position detection device for detecting a horizontal position of the wafer when transferring the wafer. In the apparatus disclosed in Japanese Laid-open Patent Publication No. 2008-066372, the substrate transfer device has a plurality of pins that support the wafer, and a driving unit that drives the pins in horizontal directions (X and Y directions). The substrate position detection device also has a plurality of imaging units for imaging a periphery of the wafer. In the apparatus disclosed in Japanese Laid-open Patent Publication No. 2008-066372, when the substrate transfer device receives the wafer from the transfer arm and mounts the wafer on the mounting table, the pins are driven horizontally for each wafer based on the imaging results from each imaging unit, thereby correcting the horizontal positional deviation of the wafer.

### SUMMARY

The technology described herein improves throughput when at least two substrates are transferred.

One embodiment according to the present disclosure provides a substrate transfer system comprising a transfer unit having a holding member configured to hold at least two substrates as a set parallel to a horizontal direction, and the transfer member transferring each of the substrates held by the holding member from a transfer source to a transfer destination, a plurality of mounting tables that are provided to the transfer destination, each of the substrates held by the holding member being respectively mounted on the plurality of mounting tables at the transfer destination, support members that are provided to each of the mounting tables and are capable of moving relatively in a vertical direction with respect to each of the mounting tables, the support members supporting each of the substrates during mounting each of the substrates on each of the mounting tables from the holding member and separating each of the substrates from the holding member, and a plurality of movement units that independently move each of the support members in the horizontal direction, wherein a position adjustment of each of the substrates with respect to each of the mounting tables is performed by a first substrate movement, in which each of the substrates in a state of being held by the holding member on each of the mounting tables is moved by the transfer unit, and a second substrate movement, in which each of the substrates in a state of being supported by each of the support members on each of the mounting tables is moved by the movement units.

### BRIEF DESCRIPTION OF THE DRAWINGS

FIG. 1 is a top schematic diagram schematically illustrating an example of a configuration of a substrate transfer system according to a first embodiment of the technology described herein.

FIG. 2A is a three-face diagram sequentially illustrating an example of an operating state of the substrate transfer system illustrated in FIG. 1.

FIG. 2B is a three-face diagram sequentially illustrating an example of an operating state of the substrate transfer system illustrated in FIG. 1.

FIG. 2C is a three-face diagram sequentially illustrating an example of an operating state of the substrate transfer system illustrated in FIG. 1.

FIG. 2D is a three-face diagram sequentially illustrating an example of an operating state of the substrate transfer system illustrated in FIG. 1.

FIG. 2E is a three-face diagram sequentially illustrating an example of an operating state of the substrate transfer system illustrated in FIG. 1.

FIG. 2F is a three-face diagram sequentially illustrating an example of an operating state of the substrate transfer system illustrated in FIG. 1.

FIG. 2G is a three-face diagram sequentially illustrating an example of an operating state of the substrate transfer system illustrated in FIG. 1.

FIG. 2H is a three-face diagram sequentially illustrating an example of an operating state of the substrate transfer system illustrated in FIG. 1.

FIG. 2I is a three-face diagram sequentially illustrating an example of an operating state of the substrate transfer system illustrated in FIG. 1.

FIG. 2J is a three-face diagram sequentially illustrating an example of an operating state of the substrate transfer system illustrated in FIG. 1.

FIG. 3 is a top schematic diagram schematically illustrating an example of a configuration of a substrate transfer system according to a second embodiment of the technology described herein.

### DETAILED DESCRIPTION

In the technology of Japanese Laid-open Patent Publication No. 2008-066372 described above, since it is necessary to drive pins in both X and Y directions, the structure of a pin driving unit becomes complicated, and the cost also increases. Accordingly, it has been proposed to eliminate the need to move a wafer by the pins by using a transfer arm to move the wafer during alignment. It has also been proposed that the transfer arm transfers a plurality of wafers in order to improve the efficiency of wafer transfer or processing.

However, at the time when the transfer arm transfers the plurality of wafers, when the transfer arm is used to align the wafers, it is necessary to move the transfer arm in the X and Y directions when each wafer is aligned. Accordingly, the throughput of alignment of all wafers may be degraded.

Hereinafter, an embodiment of the technology according to the present disclosure will be described with reference to the drawings. However, the configurations described in the following embodiments are merely examples, and an embodiment of the present disclosure are not limited to these configurations. For example, each portion or unit included in this configuration may be replaced with any other that may exert a similar function. In addition, any component may be added.

### First Embodiment

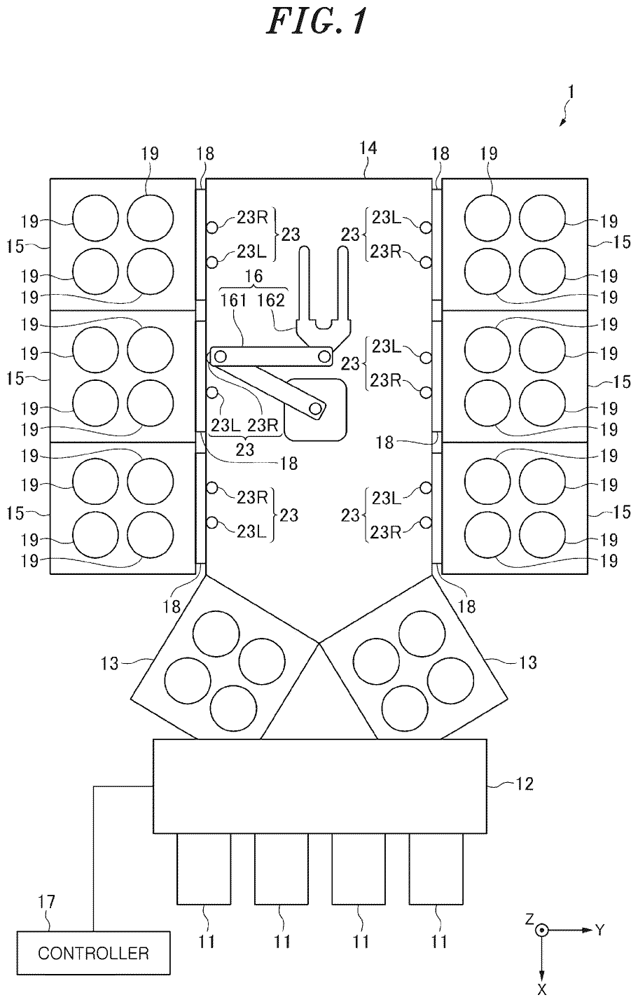

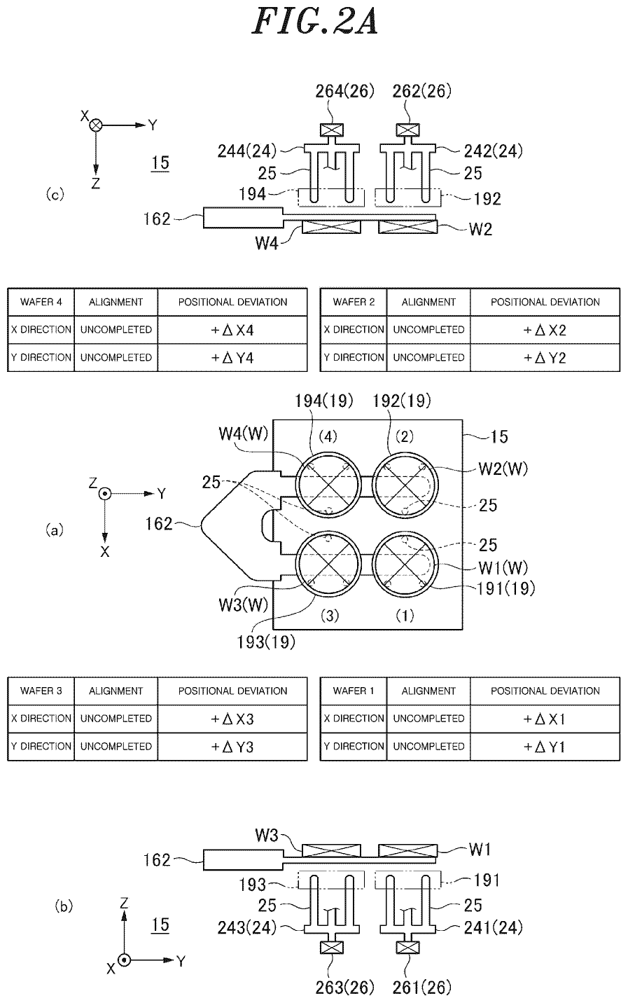

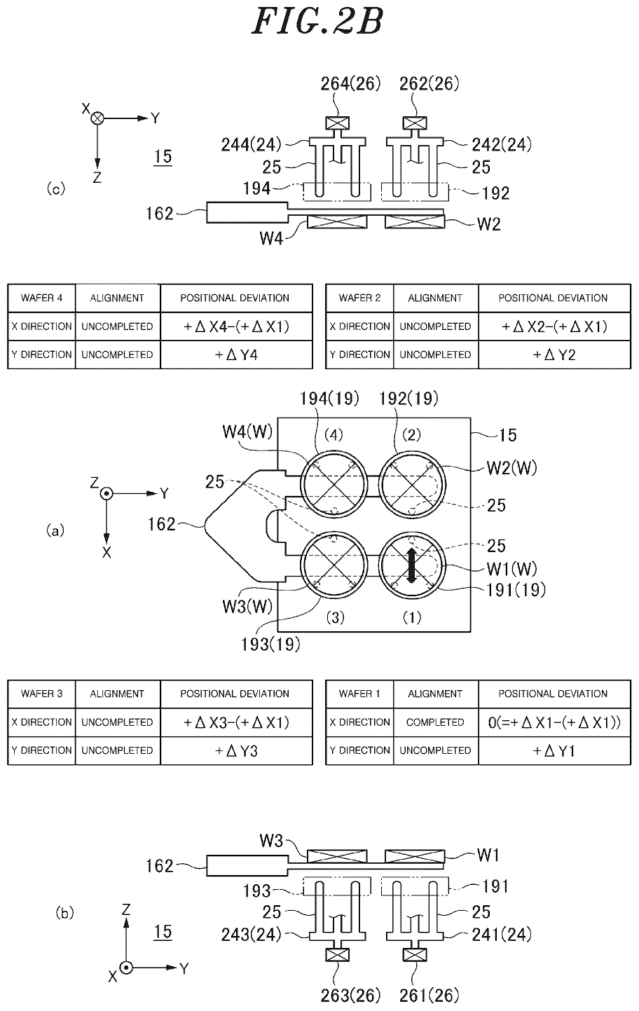

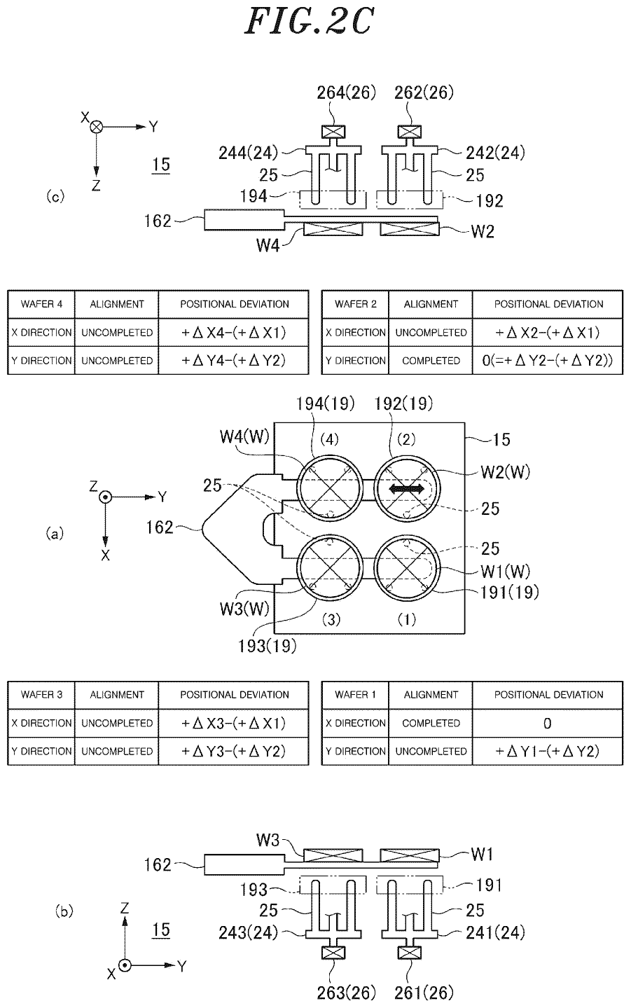

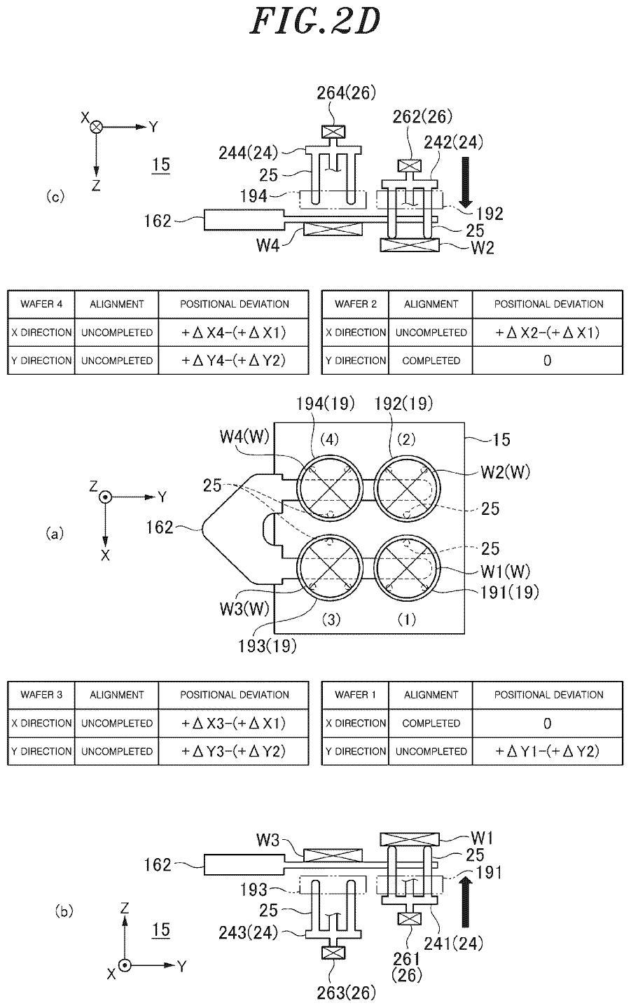

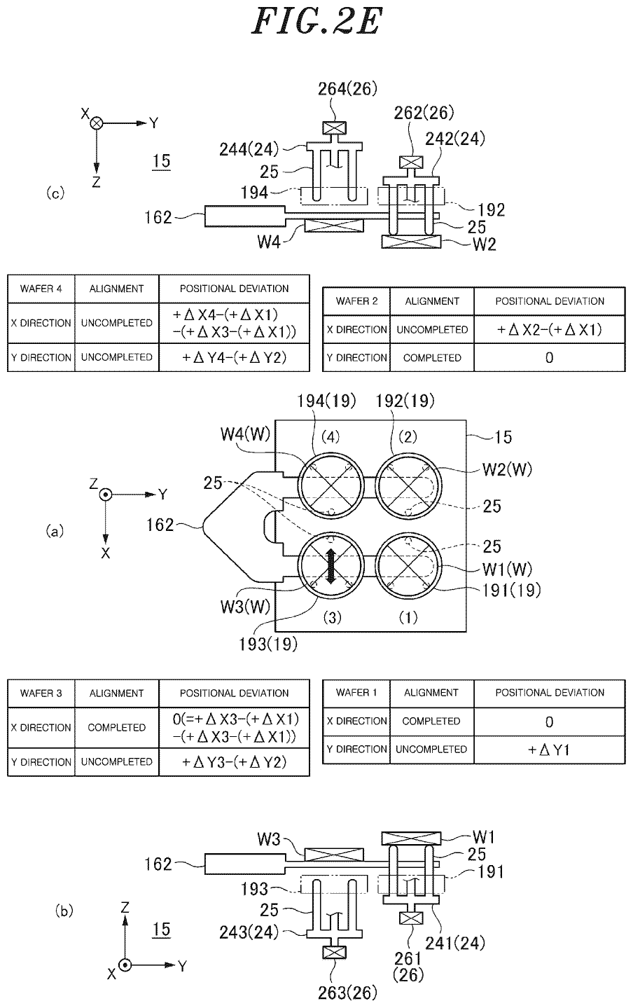

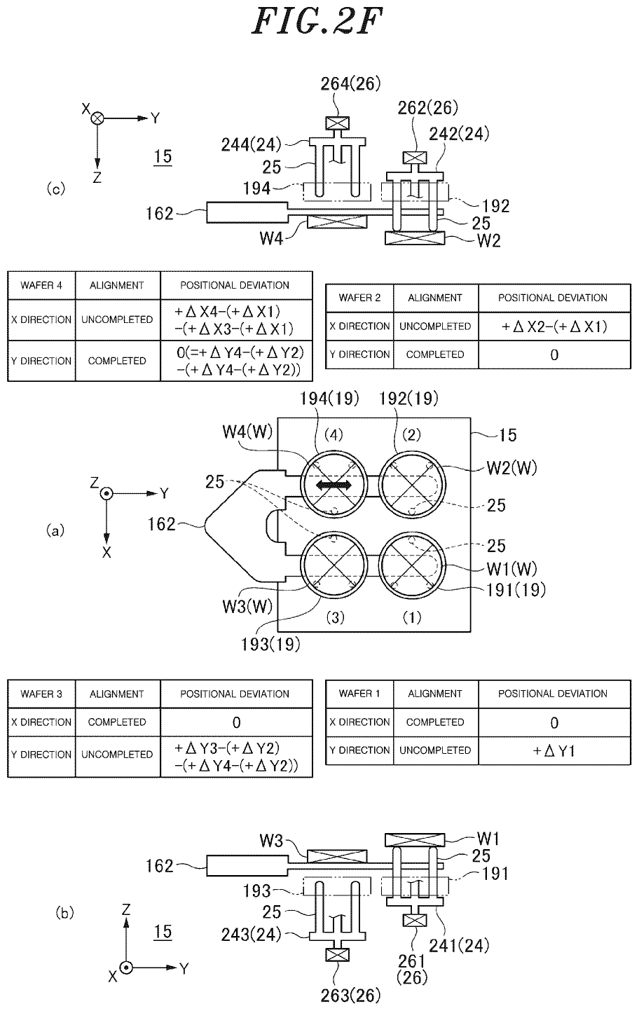

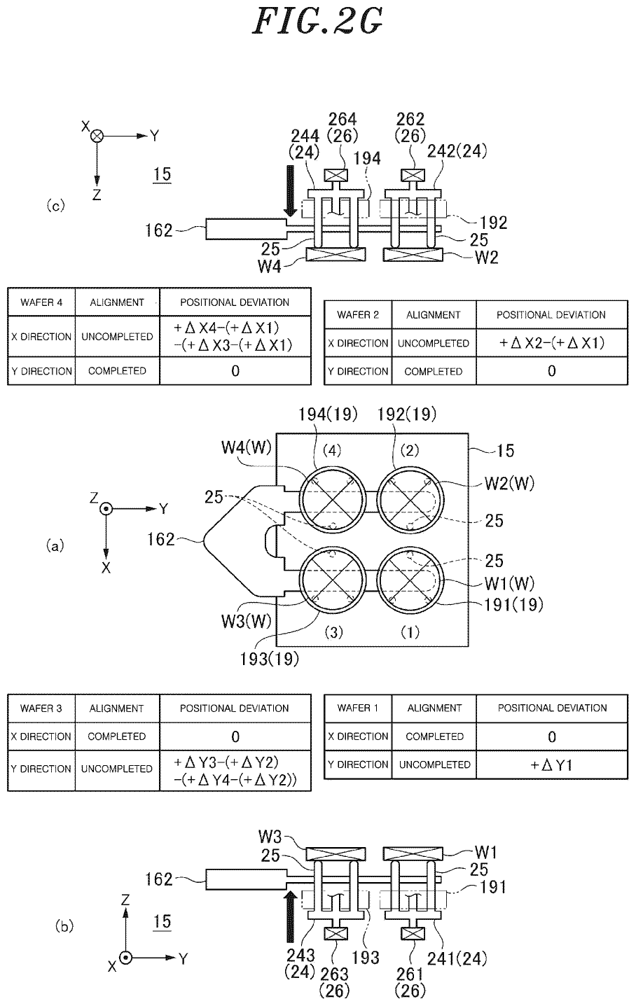

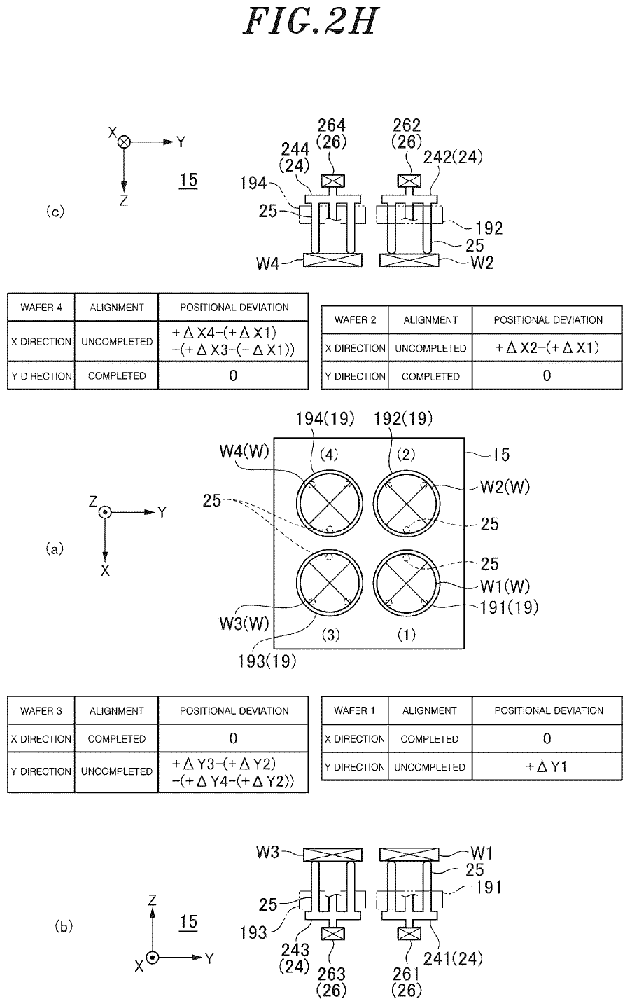

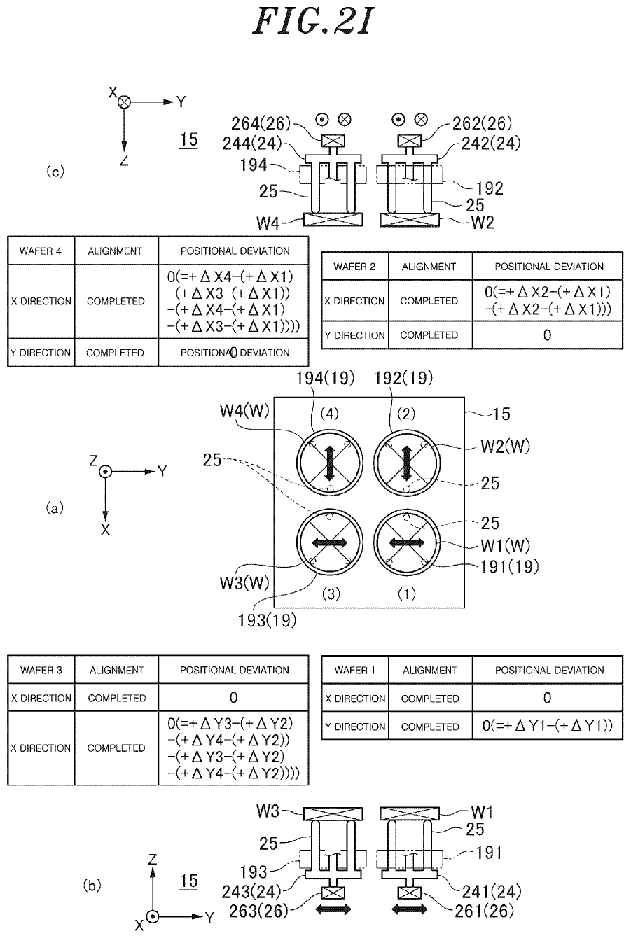

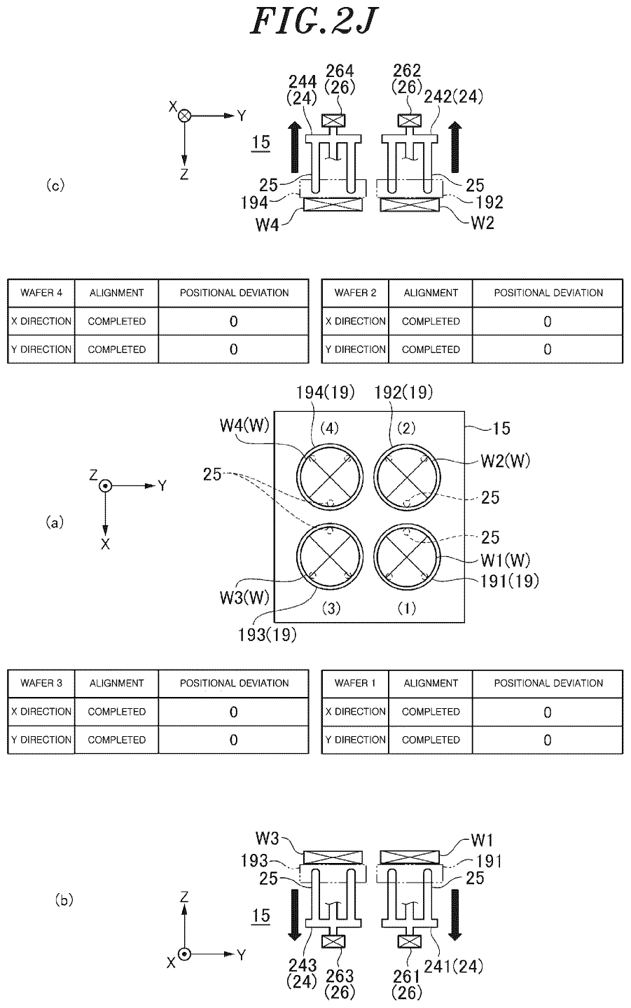

Hereinafter, the first embodiment will be described with reference to FIGS. 1 to 2J. In each drawing, three mutually orthogonal directions are assumed, two mutually orthogonal horizontal directions are called an “X direction” and a “Y direction,” and a vertical direction is called a “Z direction.” In addition, the direction in which each arrow indicates is called a “positive side (or +)” and the opposite direction is called a “negative side (or −).” FIG. 1 is a top schematic diagram schematically illustrating an example of a configuration of a substrate transfer system according to a first embodiment of the technology described herein. A substrate transfer system 1 illustrated in FIG. 1 is a system for transferring a semiconductor wafer (hereinafter referred to as a “wafer W”) having a diameter of, for example, 300 mm to 450 mm (φ300 mm to φ450 mm) as a substrate. The substrate transfer system 1 includes a load port 11, a loader module (loader chamber) 12, a load lock module (load lock chamber) 13, a transfer module (substrate transfer chamber) 14, and a process module (substrate processing chamber) 15.

A FOUP (not shown), which is a container for accommodating the plurality of wafers W, is mounted on the load port 11. In this embodiment, four load ports 11 are disposed along the Y direction, but the number of load ports 11 disposed is not limited to four. The loader module 12 is disposed adjacent to these four load ports 11 on the negative side in the X direction. The inside of the loader module 12 is always at atmospheric pressure. A transfer robot (not shown) for loading and unloading the wafer W into and from the FOUP is also disposed within the loader module 12. As a result, in the loader module 12, the wafer W is transferred between the FOUP mounted on the load port 11 and a load lock module 13. On the negative side in the X direction of the loader module 12, two load lock modules 13 are disposed adjacent to each other. The two load lock modules 13 are disposed along the Y direction. Each load lock module 13 is configured so that its interior may be selectively switched between a vacuum atmosphere and an atmospheric pressure atmosphere. In addition, the interior of each load lock module 13 is kept at the atmospheric pressure when communicating with the loader module 12, and is kept at the vacuum pressure when communicating with the transfer module 14. Each load lock module 13 serves as an intermediate transfer chamber for transferring the wafer W between the loader module 12 and the transfer module 14.

The transfer module 14 is disposed adjacent to the two load lock modules 13 on the negative side in the X direction. The interior of the transfer module 14 is always kept at a predetermined vacuum level. In addition, in the transfer module 14, a transfer robot 16 serving as a transfer unit for transferring the wafer W is disposed. The transfer robot 16 has an articulated arm 161 and a fork (pick) 162 that is attached to the tip of the articulated arm 161 and has a substantially U-shape (long shape) in a plan view. The fork 162 is a holding member that collectively holds at least two wafers W disposed in a matrix in a horizontal direction. The number of wafers W that may be held by the forks 162 is a maximum of four in this embodiment (see, for example, FIG. 2A), but is not limited thereto. In addition, the forks 162 may stably hold each wafer W by, for example, static electricity. In addition, the transfer robot 16 may transfer each wafer W from a transfer source to a transfer destination by extending and contracting the articulated arm 161 while each wafer W is held by the fork 162. This transfer includes transfer between the process modules 15 or transfer between the process module 15 and the load lock module 13.

In addition, the substrate transfer system 1 includes a sensor pair 23 as a detection unit for detecting the position of each wafer W relative to the forks 162 during the transfer. The sensor pair 23 is disposed so as to be opposite in front of each process module 15 inside the transfer module 14, and includes a left sensor 23L on a left side facing the process module 15 and a right sensor 23R on a right side facing the process module 15. In each sensor pair 23, the right sensor 23R and the left sensor 23L are separated from each other by a distance smaller than the diameter of the wafer W, and are both disposed so as to be opposite to the back surface of the wafer W transferred by the transfer robot 16. Each of the right sensor 23R and the left sensor 23L detects the passage of an outer edge (hereinafter simply referred to as an “edge”) of the wafer W above. In addition, the substrate transfer system 1 includes a controller 17 that controls the operation of each component of the substrate transfer system 1 (such as the transfer robot 16). The controller 17 includes a CPU, a memory, and the like. The CPU executes a substrate position adjustment method, which will be described later, in accordance with a program stored in a memory or the like. The controller 17 calculates the position of each wafer W relative to the fork 162 when the edge of the wafer W passes above the right sensor 23R or the left sensor 23L, specifically, the central position of each wafer W, from the encoder values of three motors of the transfer robot 16. In addition, the positions of the sensor pair 23 for detecting the position of each wafer W are not limited to the positions of the sensor pair 23 illustrated in FIG. 1.

Six process modules 15 are disposed adjacent to the transfer module 14 with gate valves 18 interposed therebetween. In this embodiment, three out of six process modules 15 are disposed along the X direction on the positive side in the Y direction of the transfer module 14, and the remaining three process modules 15 are disposed along the X direction on the negative side in the Y direction of the transfer module 14. The gate valve 18 controls communication between the transfer module 14 and the process module 15. The interior of each process module 15 is kept at a predetermined vacuum level. In addition, a plurality of mounting tables 19 are disposed in each process module 15. The wafers W held by the forks 162 are mounted on the mounting tables 19 one by one. In addition, the wafer W mounted on the mounting table 19 is subjected to a predetermined plasma processing, such as a plasma etching processing. In this embodiment, four mounting tables 19 are disposed in each process module 15. These four mounting tables 19 are disposed in pairs along the X direction and the Y direction. In addition, the number of dispositions and disposition patterns of the mounting tables 19 are not limited to the number of dispositions and disposition patterns of the mounting tables 19 illustrated in FIG. 1.

As illustrated in FIGS. 2A to 2J, each mounting table 19 is provided with a lifter 24 that is movable in an up-down direction relative to the mounting table 19, in other words, in the Z direction. The lifter 24 is a support member that temporarily lifts up and supports each wafer W from below while each wafer W on the forks 162 is being mounted on each mounting table 19 from the forks 162. This support allows each wafer W to be separated from the forks 162. Each lifter 24 has three pins 25 that protrude upward, i.e., toward the positive side in the Z direction and are separated from one another in a horizontal direction. These three pins 25 enable the wafer W to be supported at three points. This allows the wafer W to be stably maintained in a horizontal posture. In addition, the number of pins 25 that the lifter 24 has is preferably at least 3, and there is no limitation on the number. In addition, the lifter 24 is connected to a drive source (not shown) such as a motor or an air cylinder, and may be moved up and down by the drive source.

A piezo actuator 26 is connected to each lifter 24 as a movement unit for independently moving the lifter 24 in the horizontal direction. In addition, the direction in which each piezo actuator 26 moves the lifter 24 varies depending on the lifter 24 to which the piezo actuator 26 is connected, but is either the X direction or the Y direction. The piezo actuator 26 is used for adjusting (finely adjusting) the position when the wafer W is mounted on the mounting table 19. The piezo actuator 26 is relatively small, but depending on its type, is easily connected to the lifter 24, and has high resolution in position adjustment. In this embodiment, the piezo actuator 26 is used as the movement unit for independently moving the lifter 24 in the horizontal direction, without being limited thereto, and for example, a servo motor or the like may also be used.

Next, a substrate position adjustment method will be described with reference to FIGS. 2A to 2J. Each of FIGS. 2A to 2J is a three-face diagram sequentially illustrating an example of an operating state of the substrate transfer system illustrated in FIG. 1. In these drawings, (a) is a top view, and (b) and (c) are side views. The substrate position adjustment method includes a position adjustment process of adjusting the position of each wafer W with respect to each mounting table 19 using the substrate transfer system 1. In addition, herein, one out of six process modules 15 will be representatively described as a transfer destination of the wafer W to be subjected to the position adjustment process.

As illustrated in FIG. 2A, in the process module 15, two wafers W are held side by side in the X direction at a tip end side (positive side in the Y direction) of the fork 162, and two wafers W are also held side by side in the X direction at a base end side (negative side in the Y direction). In other words, in the process module 15, two wafers W are held by the forks 162 along the X direction and the Y direction. Hereinafter, among these four wafers W, the wafer W located on the most positive side in the X and Y directions will be referred to as “wafer W1,” the wafer W located on the negative side of the wafer W1 in the X direction will be referred to as “wafer W2,” the wafer W located on the negative side of the wafer W1 in the Y direction will be referred to as “wafer W3,” and the wafer W located on the negative side of the wafer W3 in the X direction will be referred to as “wafer W4.” In addition, the mounting table 19 on which the wafer W1 is mounted is referred to as a “mounting table 191,” the mounting table 19 on which the wafer W2 is mounted is referred to as a “mounting table 192,” the mounting table 19 on which the wafer W3 is mounted is referred to as a “mounting table 193,” and the mounting table 19 on which the wafer W4 is mounted is referred to as “mounting table 194.” In addition, the lifter 24 that lifts and lowers the wafer W1 is referred to as a “lifter 241,” the lifter 24 that lifts and lowers the wafer W2 is referred to as “lifter 242,” the lifter 24 that lifts and lowers the wafer W3 is referred to as a “lifter 243,” and the lifter 24 that lifts and lowers the wafer W4 is referred to as a “lifter 244.” Furthermore, the piezo actuator 26 that moves lifter 241 horizontally is referred to as “piezo actuator 261,” the piezo actuator 26 that moves the lifter 242 horizontally is referred to as a “piezo actuator 262,” the piezo actuator 26 that moves the lifter 243 horizontally is referred to as a “piezo actuator 263,” and the piezo actuator 26 that moves the lifter 244 horizontally is referred to as “piezo actuator 264.” In addition, the direction in which the piezo actuator 261 moves the lifter 241 is the Y direction, the direction in which the piezo actuator 262 moves the lifter 242 is the X direction, the direction in which the piezo actuator 263 moves the lifter 243 is the Y direction, and the direction in which the piezo actuator 264 moves the lifter 244 is the X direction.

As illustrated in FIG. 2A, the fork 162 enters the process module 15 while holding the wafers W1 to W4 and stops. In this connection, the wafer W1 is positioned on the mounting table 191, the wafer W2 is positioned on the mounting table 192, the wafer W3 is positioned on the mounting table 193, and the wafer W4 is positioned on the mounting table 194. In addition, the position adjustment (alignment) of the wafers W1 to W4 has not yet been performed. In other words, the wafer W1 is in a state where a positional deviation of “+ΔX1” occurs in the X direction and a positional deviation of “+ΔY1” occurs in the Y direction. The wafer W2 is in a state where a positional deviation of “+ΔX2” occurs in the X direction and a positional deviation of “+ΔY2” occurs in the Y direction. The wafer W3 is in a state where a positional deviation of “+ΔX3” occurs in the X direction and a positional deviation of “+ΔY3” occurs in the Y direction. The wafer W4 is in a state where a positional deviation of “+ΔX4” occurs in the X direction and a positional deviation of “+ΔY4” occurs in the Y direction. Such positional deviation amounts (deviation amounts) are arithmetically operated by the controller 17 based on the detection results detected by the sensor pair 23. Accordingly, in this embodiment, the controller 17 has a function as an arithmetic operation unit. The position adjustment process starts from this state.

First, from the state illustrated in FIG. 2A, the positional deviation in the X direction of the wafer W1 (one wafer W) of the wafers W1 and W2 positioned on the tip end side is eliminated. As illustrated in FIG. 2B, the fork 162 (transfer robot 16) is moved by “+ΔX1” on the negative side in the X direction (a first substrate movement). By the first substrate movement, the positional deviation of the wafer W1 in the X direction is eliminated, in other words, offset (no positional deviation in the X direction), and the position adjustment of the wafer W1 in the X direction is completed. In this connection, with the first substrate movement of the wafer W1, a new deviation amount “+ΔX1” on the negative side in the X direction is added to the original deviation amount “+ΔX2” in the X direction for the wafer W2. As a result, the entire deviation amount (total deviation amount) of the wafer W2 in the X direction becomes “+ΔX2−(+ΔX1).” Similarly, for the wafer W3, a new deviation amount “(+ΔX1)” on the negative side in the X direction is added to the original deviation amount “+ΔX3” in the X direction during the first substrate movement of the wafer W1. As a result, the entire misalignment amount of the wafer W3 in the X direction becomes “+ΔX3−(+ΔX1).” In addition, with the first substrate movement of the wafer W1, a new deviation amount “+ΔX1” on the negative side in the X direction is added to the original deviation amount “+ΔX4” in the X direction for the wafer W4. As a result, the entire deviation amount of the wafer W4 in the X direction becomes “+ΔX4−(+ΔX1).” The arithmetic operation of each of the entire deviation amount is also performed by the controller 17 (the same applies to the entire deviation amounts below, in other words, the movement amounts during each substrate movement).

Next, the positional deviation in the Y direction of the wafer W2 (the other wafer W) from the state illustrated in FIG. 2B is eliminated. As illustrated in FIG. 2C, the fork 162 is moved by “+ΔY2” on the negative side in the Y direction (the first substrate movement). By the first substrate movement, the positional deviation of the wafer W2 in the Y direction is eliminated (no positional deviation in the Y direction), and the position adjustment of the wafer W2 in the Y direction is completed. In this connection, with the first substrate movement of the wafer W2, a new deviation amount “+ΔY2” on the negative side in the Y direction is added to the original deviation amount “+ΔY1” in the Y direction for the wafer W1. Similarly, for the wafer W3, a new deviation amount “+ΔY2” on the negative side in the Y direction is added to the original deviation amount “+ΔY3” in the Y direction during the first substrate movement of the wafer W2. As a result, the entire deviation amount of the wafer W3 in the Y direction becomes “+ΔY3−(+ΔY2).” In addition, with the first substrate movement of the wafer W2, a new deviation amount “+ΔY2” on the negative side in the Y direction is added to the original deviation amount “+ΔY4” in the Y direction for the wafer W4. As a result, the entire deviation amount of the wafer W4 in the Y direction becomes “+ΔY4−(+ΔY2).”

Next, as illustrated in FIG. 2D, the lifter 241 is moved to the positive side (upward) in the Z direction, and the lifter 242 is also moved to the positive side in the Z direction. In this connection, the wafer W1 moves up and is separated from the fork 162 while the positional deviation in the X direction is eliminated. The wafer W2 moves up and is separated from the fork 162 while the positional deviation in the Y direction is eliminated.

Next, the positional deviation in the X direction of the wafer W3 (one wafer W) of the wafers W3 and W4 positioned on the base end side from the state illustrated in FIG. 2D is eliminated. As illustrated in FIG. 2E, the fork 162 is moved to the negative side in the X direction by the entire deviation amount “+ΔX3−(+ΔX1)” described above (the first substrate movement). By the first substrate movement, the positional deviation of the wafer W3 in the X direction is eliminated (no positional deviation in the X direction), and the position adjustment of the wafer W3 in the X direction is completed. In this connection, with the first substrate movement of the wafer W3, a new deviation amount “+ΔX3−(+ΔX1)” on the negative side in the X direction is added to the previous (original) deviation amount “+ΔX4−(+ΔX1)” in the X direction for the wafer W4. As a result, the entire deviation amount of the wafer W4 in the X direction becomes “+ΔX4−(+ΔX1)−(+ΔX3−(+ΔX1)).”

Next, the positional deviation in the Y direction of the wafer W4 (the other wafer W) from the state illustrated in FIG. 2E is eliminated. As illustrated in FIG. 2F, the fork 162 is moved to the negative side in the Y direction by the entire deviation amount “+ΔY4−(+ΔY2)” described above (the first substrate movement). By the first substrate movement, the positional deviation of the wafer W4 in the Y direction is eliminated (no positional deviation in the Y direction), and the position adjustment of the wafer W4 in the Y direction is completed. In this connection, with the first substrate movement of the wafer W4, a new deviation amount “+ΔY4−(+ΔY2)” on the negative side in the Y direction is added to the previous deviation amount “+ΔY3−(+ΔY2)” in the Y direction for the wafer W3. As a result, the entire deviation amount of the wafer W3 in the Y direction becomes “+ΔY3−(+ΔY2)−(+ΔY4−(+ΔY2)).”

Next, as illustrated in FIG. 2G, the lifter 243 is moved to the positive side (upward) in the Z direction, and the lifter 244 is also moved to the positive side in the Z direction. In this connection, the wafer W3 moves up and is separated from the fork 162 while the positional deviation in the X direction is eliminated. The wafer W4 moves up and is separated from the fork 162 while the positional deviation in the Y direction is eliminated.

As described above, all of the wafers W1 to W4 are separated from the fork 162. From this state, as illustrated in FIG. 2H, the fork 162 is moved to the negative side in the Y direction and retreated from the process module 15.

Next, from the state illustrated in FIG. 2H, the positional deviation in the Y direction of the wafer W1 is eliminated, the positional deviation in the X direction of the wafer W2 is eliminated, the positional deviation in the Y direction of the wafer W3 is eliminated, and the positional deviation in the X direction of the wafer W4 is eliminated. In addition, as described above, the positional deviation in the X direction of the wafer W1, the positional deviation in the Y direction of the wafer W2, the positional deviation in the X direction of the wafer W3, and the positional deviation in the Y direction of the wafer W4 have all already been eliminated. As illustrated in FIG. 2I, the lifter 241 is moved by the piezo actuator 261 to the negative side in the Y direction by “+ΔY1” (a second substrate movement). By the second substrate movement, the positional deviation of the wafer W1 in the Y direction is eliminated (no positional deviation in the Y direction), and the position adjustment of the wafer W1 in the Y direction is completed. In addition, the lifter 242 is moved to the negative side in the X direction by the entire deviation amount “+ΔX2−(+ΔX1)” described above by the piezo actuator 262 (the second substrate movement). By the second substrate movement, the positional deviation of the wafer W2 in the X direction is eliminated (no positional deviation in the X direction), and the position adjustment of the wafer W2 in the X direction is completed. In addition, the lifter 243 is moved to the negative side in the Y direction by the piezo actuator 263 by the entire deviation amount “+ΔY3−(+ΔY2)−(+ΔY4−(+ΔY2))” described above (the second substrate movement). By the second substrate movement, the positional deviation of the wafer W3 in the Y direction is eliminated (no positional deviation in the Y direction), and the position adjustment of the wafer W3 in the Y direction is completed. In addition, the lifter 244 is moved to the negative side in the X direction by the piezo actuator 264 by the entire deviation amount “+ΔX4−(+ΔX1)−(+ΔX3−(+ΔX1))” described above (the second substrate movement). By the second substrate movement, the positional deviation of the wafer W4 in the X direction is eliminated (no positional deviation in the X direction), and the position adjustment of the wafer W4 in the X direction is completed.

Next, as illustrated in FIG. 2J, the lifters 241 to 244 are each moved to the negative side (downward) in the Z direction. As a result, the wafer W1 is lowered with its positional deviation in the X and Y directions eliminated, and is mounted on the mounting table 191 in an accurately positioned state. Similarly, the wafer W2 is also lowered with its positional deviation in the X and Y directions eliminated, and is mounted on the mounting table 192 in an accurately positioned state. In addition, the wafer W3 is also lowered with its positional deviation in the X and Y directions eliminated, and is mounted on the mounting table 193 in an accurately positioned state. In addition, the wafer W4 is also lowered with its positional deviation in the X and Y directions eliminated, and is mounted on the mounting table 194 in an accurately positioned state.

As described above, in the position adjustment process, for the position adjustment of the wafer W1, the first substrate movement (see FIG. 2B) is performed in which the wafer W1 held by the fork 162 on the mounting table 191 is moved in the X direction by the transfer robot 16, and the second substrate movement (see FIG. 2I) is performed in which the wafer W1 supported by the lifter 241 on the mounting table 191 is moved in the Y direction by the piezo actuator 261. In addition, for the position adjustment of the wafer W2, the first substrate movement (see FIG. 2C) is performed in which the wafer W2 held by the fork 162 on the mounting table 192 is moved in the Y direction by the transfer robot 16, and the second substrate movement (see FIG. 2I) is performed in which the wafer W2 supported by the lifter 242 on the mounting table 192 is moved in the X direction by the piezo actuator 262. In addition, for the position adjustment of the wafer W3, the first substrate movement (see FIG. 2E) is performed in which the wafer W3 held by the fork 162 on the mounting table 193 is moved in the X direction by the transfer robot 16, and the second substrate movement (see FIG. 2I) is performed in which the wafer W3 supported by the lifter 243 on the mounting table 193 is moved in the Y direction by the piezo actuator 263. In addition, for the position adjustment of the wafer W4, the first substrate movement (see FIG. 2F) is performed in which the wafer W4 held by the fork 162 on the mounting table 194 is moved in the Y direction by the transfer robot 16, and the second substrate movement (see FIG. 2I) is performed in which the wafer W4 supported by the lifter 244 on the mounting table 194 is moved in the X direction by the piezo actuator 264.

Conventionally, when the transfer arm transfers a plurality of wafers as described above, when the transfer arm aligns the wafers, the transfer arm needs to move in the X and Y directions at the time when each wafer is aligned. As a result, there is a risk that the throughput up to the alignment of all wafers will deteriorate.

In this regard, the substrate transfer system 1 (the substrate position adjustment method) allocates the position adjustment in the X direction and the Y direction for each wafer W to the transfer robot 16 and the piezo actuator 26. This eliminates the need to move the transfer robot 16 (the transfer arm) in the X and Y directions when the wafers W1 to W4 are aligned, thereby improving the throughput of aligning the wafers W1 to W4. In addition, since the piezo actuator 26 is only required to be responsible for adjusting the position in either the X direction or the Y direction, the positioning configuration may be simplified compared to, for example, a configuration in which the piezo actuator 26 is responsible for adjusting the position both in the X direction and the Y direction.

In addition, in the position adjustment process, the position adjustment for the wafers W1 and W2 on the tip end side is performed prior to the position adjustment for the wafers W3 and W4 on the base end side. Accordingly, the wafers W1 and W2 are separated from the fork 162 prior to the wafers W3 and W4. Conversely, a case in which the wafers W3 and W4 are separated from the fork 162 prior to the wafers W1 and W2 is considered. In this case, for example, even when an attempt is made to retract the fork 162 from the process module 15 due to various reasons, such as an error, the wafer W1 on the fork 162 may collide with the pin 25 of the lifter 243, and the wafer W2 on the fork 162 may collide with the pin 25 of the lifter 244, thereby preventing the retraction. However, in the aforementioned position adjustment process, the wafers W1 and W2 are separated from the fork 162 prior to the wafers W3 and W4, so that the fork 162 may be quickly retracted from the process module 15. In addition, when there is no possibility of retracting the fork 162 from the process module 15 during the alignment of each wafer, the position adjustment for the wafers W3 and W4 may be performed prior to the position adjustment for the wafers W1 and W2.

In addition, the operation to the position where the first substrate movement in FIG. 2A has not been performed does not have to be performed, and the first substrate movement of the wafer W1 in the X direction (see FIG. 2B) and the first substrate movement of the wafer W2 in the Y direction (see FIG. 2C) may be performed at the same timing. Similarly, the first substrate movement of the wafer W3 in the X direction (see FIG. 2E) and the first substrate movement of the wafer W4 in the Y direction (see FIG. 2F) may be performed at the same timing. In this connection, the first substrate movement of the wafers W1 and W2 and the first substrate movement of the wafers W3 and W4 are performed at different timings. This is because the transfer robot 16 may adjust one position in each of the X and Y directions at a time. Hence, when the fork 162 holds the positional relationship between the wafers W1 to W4, the first substrate movement in the X direction and the first substrate movement in the Y direction may not be performed at the same timing for the wafers W1, W3 and W4. On the other hand, the second substrate movement of the wafer W1 in the Y direction, the second substrate movement of the wafer W2 in the X direction, the second substrate movement of the wafer W3 in the Y direction, and the second substrate movement of the wafer W4 in the X direction are performed at the same timing (see FIG. 2I). This is because each piezo actuator 26 is configured to activate independently, so that the second substrate movement in the X direction and the second substrate movement in the Y direction may be performed at the same timing. In addition, the performance of the second substrate movement in the X direction and the second substrate movement in the Y direction at the same timing contributes to improving the throughput of alignment of each wafer.

In this embodiment, the number of wafers W held by the forks 162 is even. In this connection, in the position adjustment process, the position adjustment by the first substrate movement and the second substrate movement is repeated for each pair of wafers W disposed along the X direction, thereby making it possible to adjust the positions of all wafers W. In addition, after the state illustrated in FIG. 2D, the second substrate movement of the wafer W1 in the Y direction and the second substrate movement of the wafer W2 in the X direction may be performed. In this connection, the second substrate movement of the wafer W1 in the Y direction and the second substrate movement of the wafer W2 in the X direction in the state illustrated in FIG. 2I are omitted.

### Second Embodiment

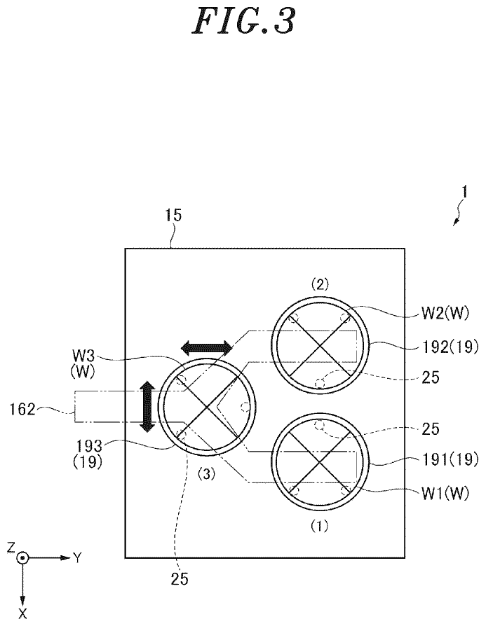

Hereinafter, the second embodiment will be described with reference to FIG. 3. The description will focus on the differences from the embodiment described above, and the explanation regarding similar matters will be omitted. This embodiment is similar to the first embodiment, except that the number of wafers held by the forks is different. Specifically, the number of wafers disposed on the forks is even in the first embodiment, but is odd in this embodiment.

FIG. 3 is a top schematic diagram schematically illustrating an example of a configuration of a substrate transfer system according to a second embodiment of the technology described herein. As illustrated in FIG. 3, in the process module 15, the wafers W1 and W2 are disposed on the tip end side of the fork 162 along the X direction, and the wafer W3 is disposed on the base end side. The X coordinate of the wafer W3 is an intermediate coordinate between the X coordinate of the wafer W1 and the X coordinate of the wafer W2. In the position adjustment process of this embodiment, the position adjustment of the wafers W1 and W2 may be performed in the same manner as the position adjustment of the wafers W1 and W2 in the first embodiment. In addition, the position of the wafer W3 is adjusted by the movement in the X and Y directions using the fork 162. This makes it possible to omit the horizontal movement of the wafer W3 while being supported by the lifter 24.

As described above, in this embodiment, when the position adjustment process is performed when the number of wafers W disposed on the fork 162 is odd, the position adjustment by the first substrate movement and the second substrate movement may be repeated for each two wafers W disposed along the X direction. Then, the remaining one wafer W is moved by the fork 162 to adjust its position. This allows all the wafers W to be mounted on the mounting table 19 in an accurately positioned state. In addition, the remaining one wafer W may also be moved in the horizontal direction by the piezo actuator 26 to adjust its position.

Hereinbefore, although the preferred embodiments of the present disclosure have been described above, the present disclosure is not limited to the aforementioned embodiments, and various modifications and changes are possible within the scope of the gist of the present disclosure.

This application claims priority to Japanese Patent Application No. 2022-178163, filed with the Japan Patent Office on Nov. 7, 2022, the entire contents of which are incorporated herein by reference.

What is claimed is:

1. A substrate transfer system, comprising:
a transfer unit having a holding member configured to hold at least two substrates as a set parallel to a horizontal direction, and the transfer unit transferring each of the at least two substrates held by the holding member from a transfer source to a transfer destination;
a plurality of mounting tables that are provided to the transfer destination, each of the at least two substrates held by the holding member being respectively mounted on the plurality of mounting tables at the transfer destination;
support members that are provided to each of the plurality of mounting tables and are capable of moving relatively in a vertical direction with respect to each of the plurality of mounting tables, the support members supporting each of the at least two substrates during mounting each of the at least two substrates on each of the plurality of mounting tables from the holding member and separating each of the at least two substrates from the holding member; and
a plurality of movement units that independently move each of the support members in the horizontal direction,
wherein a position adjustment of each of the at least two substrates with respect to each of the plurality of mounting tables is performed by a first substrate movement, in which each of the at least two substrates in a state of being held by the holding member on each of the plurality of mounting tables is moved by the transfer unit, and a second substrate movement, in which each of the at least two substrates in a state of being supported by each of the support members on each of the plurality of mounting tables is moved by the plurality of movement units.

2. The substrate transfer system of claim 1, wherein a movement direction of the first substrate movement and a movement direction of the second substrate movement are orthogonal to each other.

3. The substrate transfer system of claim 2, wherein, among the at least two substrates, a movement direction of one substrate in the first substrate movement and a movement direction of another substrate in the first substrate movement are orthogonal to each other, and a movement direction of the one substrate in the second substrate movement and a movement direction of the other substrate in the second substrate movement are orthogonal to each other.

4. The substrate transfer system of claim 3, wherein the second substrate movement of the one substrate and the second substrate movement of the other substrate are performed at a same timing.

5. The substrate transfer system of claim 3, wherein:
an X direction and a Y direction which are orthogonal to each other are assumed, the movement direction of the one substrate in the first substrate movement is the X direction, the movement direction of the other substrate in the first substrate movement is the Y direction, the movement direction of the one substrate in the second substrate movement is the Y direction, and the movement direction of the other substrate in the second substrate movement is the X direction;
the position of the one substrate in the X direction is adjusted by the first substrate movement of the one substrate; and
the position of the other substrate in the Y direction is adjusted by the first substrate movement of the other substrate.

6. The substrate transfer system of claim 5, wherein:
a new deviation amount in the Y direction of the one substrate is added to an original deviation amount in the Y direction by the first substrate movement of the other substrate, and an entire deviation amount obtained by adding the new deviation amount to the original deviation amount in the Y direction is offset by the second substrate movement to adjust the position of the one substrate in the Y direction; and
and a new deviation amount in the X direction of the other substrate is added to an original deviation amount in the X direction by the first substrate movement of the one substrate, and an entire deviation amount obtained by adding the new deviation amount to the original deviation amount in the X direction is offset by the second substrate movement to adjust the position of the other substrate in the X direction.

7. The substrate transfer system of claim 1, wherein:
the holding member is elongated and is configured to hold two of the at least two substrates at its tip end side and hold two of the at least two substrates at its base end side; and
when the position adjustment is performed, a position adjustment for the two substrates at the tip end side is performed prior to a position adjustment for the two substrates at the base end side.

8. The substrate transfer system of claim 1, wherein, when the position adjustment is performed and a number of substrates held by the holding member is even, a position adjustment by the first substrate movement and the second substrate movement is repeated for every two substrates.

9. The substrate transfer system of claim 1, wherein, when the position adjustment is performed and a number of substrates held by the holding member is odd, a position adjustment by the first substrate movement and the second substrate movement is repeated for every two substrates, and a position adjustment for the remaining one substrate is performed by movement using the transfer unit.

10. The substrate transfer system of claim 1, further comprising:
a detection unit for detecting a position of each of the at least two substrates with respect to the holding member while each of the at least two substrates is transferred from the transfer source to the transfer destination; and
an arithmetic operation unit for arithmetically operating, based on at least a detection result from the detection unit, a movement amount in the first substrate movement and a movement amount in the second substrate movement for each of the at least two substrates, respectively.

11. The substrate transfer system of claim 1, wherein at least one of the plurality of movement units comprises a piezo actuator.

12. The substrate transfer system of claim 1, wherein the support members are configured to mount each of the at least two substrates on each of the plurality of mounting tables after the position adjustment.

13. The substrate transfer system of claim 1, wherein the support members are configured to support each of the at least two substrates at least at three points.

14. A substrate position adjustment method using a substrate transfer system,
wherein the substrate transfer system comprises:
a transfer unit having a holding member configured to hold at least two substrates as a set parallel to a horizontal direction, and the transfer unit transferring each of the at least two substrates held by the holding member from a transfer source to a transfer destination;
a plurality of mounting tables that are provided to the transfer destination, each of the at least two substrates held by the holding member being respectively mounted on the plurality of mounting tables at the transfer destination;
support members that are provided to each of the plurality of mounting tables and are capable of moving relatively in a vertical direction with respect to each of the plurality of mounting tables, the support members supporting each of the at least two substrates during mounting each of the at least two substrates on each of the plurality of mounting tables from the holding member and separating each of the at least two substrates from the holding member; and
a plurality of movement units that independently move each of the support members in the horizontal direction,
wherein the substrate position adjustment method comprises:
a position adjustment process of adjusting positions of each of the at least two substrates with respect to each of the plurality of mounting tables, the position adjustment process performing a first substrate movement, in which each of the at least two substrates in a state of being held by the holding member on each of the plurality of mounting tables is moved by the transfer unit, and a second substrate movement, in which each of the at least two substrates in a state of being supported by each of the support members on each of the plurality of mounting tables is moved by the plurality of movement units.

15. The substrate position adjustment method of claim 14, wherein a movement direction of the first substrate movement and a movement direction of the second substrate movement are orthogonal to each other.

16. The substrate position adjustment method of claim 15, wherein, among the at least two substrates, a movement direction of one substrate in the first substrate movement and a movement direction of another substrate in the first substrate movement are orthogonal to each other, and a movement direction of the one substrate in the second substrate movement and a movement direction of the other substrate in the second substrate movement are orthogonal to each other.

17. The substrate position adjustment method of claim 16, wherein the second substrate movement of the one substrate and the second substrate movement of the other substrate are performed at a same timing.

18. The substrate position adjustment method of claim 16, wherein:
an X direction and a Y direction which are orthogonal to each other are assumed, the movement direction of the one substrate in the first substrate movement is the X direction, the movement direction of the other substrate in the first substrate movement is the Y direction, the movement direction of the one substrate in the second substrate movement is the Y direction, and the movement direction of the other substrate in the second substrate movement is the X direction;
the position of the one substrate in the X direction is adjusted by the first substrate movement of the one substrate; and
the position of the other substrate in the Y direction is adjusted by the first substrate movement of the other substrate.

19. The substrate position adjustment method of claim 18, wherein:
a new deviation amount in the Y direction of the one substrate is added to an original deviation amount in the Y direction by the first substrate movement of the other substrate, and an entire deviation amount obtained by adding the new deviation amount to the original deviation amount in the Y direction is offset by the second substrate movement to adjust the position of the one substrate in the Y direction; and
and a new deviation amount in the X direction of the other substrate is added to an original deviation amount in the X direction by the first substrate movement of the one substrate, and an entire deviation amount obtained by adding the new deviation amount to the original deviation amount in the X direction is offset by the second substrate movement to adjust the position of the other substrate in the X direction.
